(19) United States
(12) Patent Application Publication
(10) Pub. No.: US 2007/0066080 A1
(43) Pub. Date: Mar. 22, 2007

(54) Method of producing a substrate having areas of different hydrophilicity and/or oleophilicity on the same surface

(75) Inventors: Thomas Kugler, Cambridge (GB); Shunpu Li, Cambridge (GB); Christopher Newsome, Cambridge (GB); David Russell, Cambridge (GB)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/517,442

(22) Filed: Sep. 8, 2006

(30) Foreign Application Priority Data
Sep. 20, 2005 (GB) 0519181.2

(51) Int. Cl. H01L 21/302; H01L 21/461; H01L 21/31; H01L 21/469

(52) U.S. Cl. 438/725; 438/789

(57) ABSTRACT

The present invention relates to substrates having wetting contrasts which include a top layer of polymer matrix and particles of an inorganic material. Such substrates can be processed in various ways which allow the production of good wetting contrasts by various processing means. According to a first aspect of the present invention, a method of producing a substrate having a surface comprising adjacent areas which have different hydrophilicities and/or oleophilicities is provided. The method comprises the step of etching away polymer from an area of the surface layer of a substrate precursor which comprises inorganic particles embedded in a polymer matrix. The etching exposes the inorganic particles at the surface to form one of the adjacent areas. The present invention is further directed to methods of producing a microelectronic component which involves depositing electronically functional material onto such a substrate. Further, the present invention is directed to substrates and substrate precursors.

### FIELD OF INVENTION

The present invention relates to a method of producing a substrate having areas of different hydrophilicity and/or oleophilicity on the same surface. Such substrates have a use for example in the field of solution processing to form microelectronic devices.

### TECHNICAL BACKGROUND

Electronically functional materials such as conductors, semiconductors and insulators have many applications in modern technology. In particular, these materials are useful in the production of microelectronic components such as transistors (e.g. thin film transistors (TFTs)) and diodes (e.g. light emitting diodes (LEDs)). Inorganic materials such as elemental copper, elemental silicon, and silicon dioxide have traditionally been employed in the production of these microelectronic components, whereby they are deposited using physical vapour deposition (PVD) or chemical vapour deposition (CVD) methods. Recently, newly developed materials and material formulations with conducting, semiconducting or insulating properties have become available and are being adopted in the microelectronic industry.

One such class of electronically functional materials is that of organic semiconductor materials.

Another class is that of inorganic metal colloid formulations dispersed in liquid solvents. While the first example is a recently developed class of materials, the second example uses traditional materials in a recently developed formulation type. These materials and material formulations are associated with a number of advantages over the traditional materials when used for microelectronic device production. One such advantage is that these materials can be processed in a greater variety of ways, including for example solution processing where the material is dissolved in a solvent or dispersed as a colloid, and the resulting solution is used to manufacture e.g. microelectronic components. This is advantageous because solution processing is very cost-effective. In particular, a significant saving can be made in terms of start-up costs associated with setting up plants for producing microelectronic components when compared with e.g. silicon semiconductor processing facilities where there is a need for high capital investment in expensive production facilities.

One particularly promising technique for the processing of semiconductors to form microelectronic components, for example TFTs and LEDs, is ink-jet printing. This is because ink-jet printing conveniently allows relatively precise deposition of a semiconductor solution onto a substrate in an automated manner. It would be highly desirable to be able to produce microelectronic semiconductor components on an industrial scale by ink-jet printing conductor, semiconductor and insulator solutions onto a suitable substrate.

However, there are fundamental problems in carrying this out in practice. The key problem is that, in the production of microelectronic devices, it is generally necessary to produce high-resolution patterns of the electronically functional materials on a substrate. At present, ink-jet printing does not allow a high enough resolution to be achieved to allow the direct printing of suitable patterns onto a bare substrate. At present, there are two ways to avoid this problem.

The first way is to use photolithography to remove undesired areas of a blanket-deposited electronically functional material, very high-resolution patterns being obtainable by this method. However, photolithography is a subtractive technology and is expensive both in terms of initial investment in expensive photolithographic equipment and in terms of the relatively large number of processing steps associated with these techniques, energy consumption and wasted material.

A second way of circumventing the resolution problems associated with ink-jet printing of patterns of electronically functional materials on bare substrates is to form a pre-pattern on the substrate prior to deposition of the electronically functional material thereon which directs the inkjet-printed solution onto specific areas. Generally, this involves treating the substrate to form a wetting contrast consisting of adjacent areas on the surface having different hydrophilicity and/or oleophilicity to ensure different interaction with electronically functional inks subsequently printed thereon. Thus a substrate can be produced having ink-receptive areas and ink-repellent areas, so that a droplet of ink landing on an ink-receptive area of the substrate would be prevented from spreading onto the adjacent ink repellent area. Similarly, any droplet of ink landing so that it contacts both the ink-receptive and ink-repellent areas would be pushed towards the ink-receptive area. In this way, the resolution of an ink-jet printer can be enhanced to allow the required resolution to produce patterning as required in the production of microelectronic devices. For this to work effectively, the difference in hydrophilicity and/or oleophilicity between the two areas of the substrate should be as large as possible.

At present, this latter technique requiring the establishment of adjacent ink-receptive areas and ink-repellent areas on a substrate has only been realised on inorganic substrates such as indium tin oxide or silicon oxide (glass) plates. Where such a substrate is used, it is conventional to apply a photo-crosslinkable polymer (=negative resist) coating (for example polyimide) to an inorganic oxide plate and then selectively dissolve those parts of the polymer coating that were protected by a photomask against the UV-irradiation during a crosslinking step to reveal the underlying inorganic oxide. Subsequent treatment of the entire substrate with e.g. a CF₄ plasma leaves the exposed inorganic oxide substrate hydrophilic but renders the polymer surface hydrophobic and oleophobic thus establishing a wetting contrast. Subsequent printing of an aqueous conductor ink onto the exposed glass parts allows a high resolution pattern to be formed even if the patterning carried out is required to be of higher resolution than the ink-jet printing because droplets of aqueous ink falling in part on the hydrophobic and oleophobic polymer area will be pushed on to the hydrophilic glass area.

Whilst this method of creating adjacent ink-receptive and ink-repellent areas on the substrate is generally quite effective in increasing the resolution obtainable when ink-jet printing a solution of an electronically functional material, several problems are associated with these techniques so that there is a need for the development of new techniques which allow substrates with wetting contrasts to be produced.

The main problem with the existing substrates is that it is difficult to produce substrates having wetting contrasts having a high enough difference in hydrophilicity and/or oleophilicity between the adjacent areas making up the wetting contrast. At present, when using the conventional techniques making use of a glass plate and a polyimide, a wetting contrast would usually have to be produced by fluorinating the entire surface of the glass and polyimide substrate after having carried out the dissolving step to pattern-wise reveal the glass plate underlying the polyimide in order to produce a wetting contrast having a large enough difference in hydrophilicity and/or oleophilicity between the adjacent areas which make up the wetting contrast. The fluorination treatment fluorinates the polyimide surface rendering it hydrophobic and oleophobic but does not significantly alter the hydrophilicity of the exposed glass areas thus creating the desired wetting contrast.

However, this practice is not always suitable for preparing an appropriate substrate for ink-jet printing electronically functional materials.

Firstly, whilst the above method can be used to produce reasonably good wetting contrasts which are generally acceptable in terms of their ink-directing properties, there is still room for improvement in this area so that there is still a need for the development of new substrates having wetting contrasts where the difference in hydrophilicity and/or oleophilicity between the adjacent areas which make up the wetting contrast is even higher.

Secondly, it is a problem with the known methods that appropriate wetting contrasts can only be realised by including a step of surface-fluorination. It would be highly desirable to be able to produce a substrate having an appropriate wetting contrast without the need to carry out any fluorination step. This is because, for certain applications, it is undesirable to have fluorinated surface groups on the substrate, e.g. where the substrate has electronically functional inks deposited thereon. This is firstly because problems may arise where the fluorinated groups are in direct contact with a semiconducting polymer because the strong dipole moments associated with C—F bonds may result in the accumulation of holes at the interface between a P-type semiconducting polymer and the,substrate; this may alter the electronic properties of the semiconductor by for example increasing the off-current which is undesirable. Secondly, fluorinated surfaces famously have very low surface energies so that most substances will adhere relatively poorly to a fluorinated surface. One consequence of this is that where fluorinated surfaces are used as a substrate for ink-jet printing of e.g. micro-electronic devices, mechanical failure of the device is more likely than in similar devices produced using non-fluorinated substrates.

An additional problem with the known substrates is that they all rely on rigid substrates such as glass or indium tin oxide. Such substrates are all rigid and cannot therefore be used in reel-to-reel processing, a technique whereby a roll of unprocessed substrate is unreeled, processed and the processed substrate collected on a second reel. Such processing is most desirable to use in practice and therefore it would be a significant improvement if it were possible to solve the above problems and at the same time produce substrates which are flexible enough to allow such processing.

Accordingly, there is still a need for novel techniques of preparing substrates having wetting contrasts which allow a variety of substrates with good wetting contrasts to be produced. Specifically, there is a need to develop substrates having good wetting contrasts without the need for surface fluorination and potentially also for improving on the known fluorinated substrates to achieve even higher differences in hydrophilicity and/or oleophilicity between the areas making up the wetting contrast.

With a view to solving the above-mentioned technical problems, the present inventors set out to provide a new method of producing substrates having appropriate wetting contrasts with a view to overcoming the deficiencies of the known methods.

### BRIEF DESCRIPTION OF THE PRESENT INVENTION

According to a first aspect of the present invention, there is provided a method of producing a substrate having a surface comprising adjacent areas which have different hydrophilicities and/or oleophilicities comprising the step of etching away polymer from an area of the surface layer of a substrate precursor, the surface layer comprising inorganic particles which are embedded in a polymer matrix, the etching exposing the inorganic particles at the surface in an area corresponding to one of the adjacent areas.

According to a second aspect of the present invention, there is provided a method of producing a microelectronic component, comprising the steps of:

(i) producing a substrate or a modified substrate having adjacent areas of different hydrophilicity and/or oleophilicity on the same surface by the method defined above; and

(ii) depositing a first solution onto the substrate or the modified substrate to form an area comprising a first electronically functional material.

According to a third aspect of the present invention, there is provided a substrate precursor comprising a surface layer comprising inorganic particles which are embedded in a polymer matrix.

According to a fourth aspect of the present invention, there is provided a substrate having a surface layer comprising inorganic particles which are embedded in a polymer matrix, the substrate comprising a first surface area where inorganic particles are exposed at the surface and a second surface area, adjacent to the first surface area, where substantially no inorganic particles are exposed.

### DETAILED DESCRIPTION OF THE PRESENT INVENTION

The present inventors have investigated possible ways of producing a substrate on which it is possible to produce improved wetting contrasts.

Wetting contrasts consist of areas of differing hydrophilicity and/or oleophilicity. For the purposes of this invention, hydrophilicity of a surface is measured via its contact angle with water, whilst oleophilicity is measured via contact angles with hexane, that is the angle between a given surface and a droplet of a designated amount of the relevant liquid. Such contact angle measurements are well-known in the art, and measurements can be made using e.g. a goniometer (contact angle measuring device) to measure droplets of 1-5 μl on a surface of interest. Preferably, the wetting contrast in the substrates of the present invention have adjacent surface areas whose contact angles with water and/or hexane differ by more than 60°, preferably more than 80° and most preferably more than 100°.

For the purposes of the present invention, the word “hydrophilic” is used to describe surfaces having a contact angle with water of less than 60°. The phrase “very hydrophilic” is used to describe surfaces having a contact angle with water of less than 20°. The phrase “super-hydrophilic” is used to describe surfaces having a contact angle with water of less than 5°.

The word “hydrophobic” is used to describe surfaces having a contact angle with water of more than 60°. The phrase “very hydrophobic” is used to describe surfaces having a contact angle with water of more than 90°. The phrase “super-hydrophobic” is used to describe surfaces having a contact angle with water of more than 120°.

The word “oleophilic” is used to describe surfaces having a contact angle with hexane of less than 60°. The phrase “very oleophilic” is used to describe surfaces having a contact angle with hexane of less than 20°. The phrase “super-oleophilic” is used to describe surfaces having a contact angle with hexane of less than 50°.

The word “oleophobic” is used to describe surfaces having a contact angle with hexane of more than 60°. The phrase “very oleophobic” is used to describe surfaces having a contact angle with hexane of more than 90°. The phrase “super-oleophobic” is used to describe surfaces having a contact angle with hexane of more than 120°.

The research of the present inventors has led them to find that good wetting contrasts can be achieved when preparing a substrate by etching a substrate precursor comprising a surface layer comprising inorganic particles which are embedded in a polymer matrix to produce a substrate with a wetting contrast. The precursor is preferably obtained by coating a substrate base with a mixture of a polymer matrix and inorganic particles.

The use of such substrate precursors in the production of substrates with wetting contrasts is advantageous because it allows control over the extent to which areas of the precursor are polymer-like in behaviour and glass-like in behaviour depending on the extent to which the polymer material of the surface layer is etched away to reveal the underlying inorganic particles. Thus, depending on the concentration of the inorganic particles in the polymer and the extent to which the uppermost polymer material is removed from the surface layer, it is possible to produce regions which are essentially glass-like, essentially polymer-like or anywhere in between.

A further significant advantage of using precursors having a surface layer which comprises a polymer surface in which inorganic particles are embedded is that the surface area of the surface is increased due to the surface roughness which arises as a result of the presence of the embedded particles. This is preferable because the roughness affects the surface properties of the substrate, increasing a substrate's philicity or phobicity to a particular solvent. Thus, roughening a surface renders a hydrophilic surface more hydrophilic, a hydrophobic surface more hydrophobic, an oleophilic surface more oleophilic, and an oleophobic surface more oleophobic.

Whilst it is preferable that the two adjacent areas of the substrate having different hydrophilicities and/or oleophilicities are both derived from the surface layer of the substrate precursor, the substrate being obtained by etching only a part of the surface layer, it is also possible for one of the two areas which make up the wetting contrast to be of a different origin. Specifically, it is possible according to the present invention to deposit a further layer of a polymer different to that which is present in the surface layer on a part of the substrate precursor, the further layer of polymer constituting one of the adjacent areas making up the wetting contrast.

Furthermore, one of the areas which make up the wetting contrast may be derived from a substrate base which underlies the surface layer of the precursor where the surface layer of the precursor does not cover all of an underlying base.

Once a wetting contrast comprising areas of different hydrophilicity and/or oleophilicity has been arrived at wherein one of those areas corresponds to an etched portion of the surface layer of the substrate precursor which comprises polymer material and underlying inorganic particles, the difference in hydrophilicity and/or oleophilicity between the two areas in question can be increased by exposing the surface of the substrate to chemical treatment such as fluorination, oxidation or fluoroalkylsilation. Where an appropriate chemical treatment is chosen for a given substrate, significant increases in the difference in hydrophilicity and/or oleophilicity between the adjacent areas is observed.

It is possible to deposit further layers of polymer onto parts of the inorganic regions of the substrate or to mask areas of the substrate before subjecting it to chemical treatment, so that only selected areas of the substrate are chemically modified.

Using these techniques, it is possible to produce a substrate which has a desired wetting contrast.

In Table 1 below, the hydrophilicities and/or oleophilicities of various substances are set out. Table 1 indicates the change in hydrophilicity and/or oleophilicity achievable by various chemical treatment of these substances.

TABLE 1

| | | | | Fluoroalkylsilane |
|---|---|---|---|---|
| | No treatment | CF₄ plasma treatment | O₂ plasma treatment | treatment |
| SiO₂ | Hydrophilic | Super-Hydrophilic | Super-Hydrophilic | Very Hydrophobic |
| | | | | (smooth SiO₂ surfaces) |
| | | | | or Super-Hydrophobic |
| | | | | (rough SiO₂ surfaces) |
| | | | | & Oleophobic |
| Polymethylmethacrylate | Hydrophobic | Hydrophobic | Very Hydrophilic | — |
| (PMMA) | & Oleophilic | & Oleophobic | | |
| PMMA + SiO₂ (small | Hydrophobic | Hydrophobic | Very Hydrophilic | — |
| amount of SiO₂ on surface) | & Oleophilic | & Oleophobic | | |
| PMMA + SiO₂ (large | Very Hydrophobic | Super Hydrophilic | Super Hydrophilic | Super-Hydrophobic |
| amount of SiO₂ on surface) | & Oleophilic | | | & Oleophobic |

In the following paragraphs, the term “substrate”, possible substrate precursors and bases, polymer matrix materials, inorganic oxide and other inorganic material, etching techniques and various chemical treatments of substrates to produce various wetting contrasts will be explained in more detail. Furthermore, the use of the substrates in producing microelectronic components is discussed. Then, specific embodiments of the present invention will be described with reference to the drawings, in which:

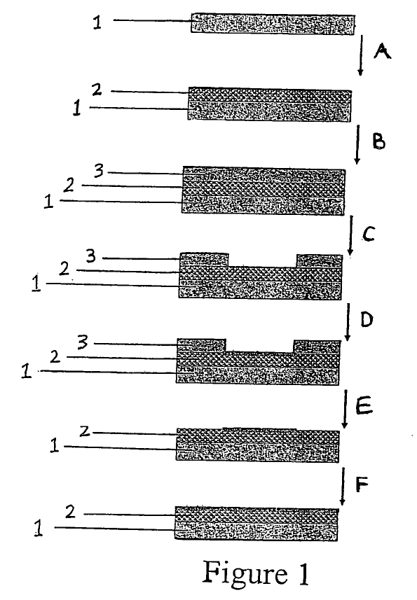

FIG. 1. schematically depicts a first method of realising the method of the present invention;

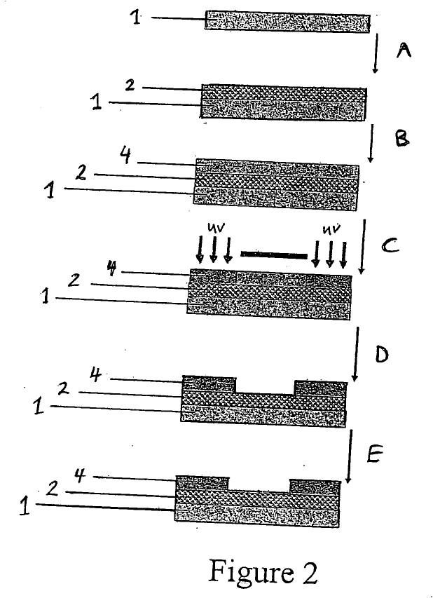

FIG. 2. schematically depicts a second method of realising the method of the present invention;

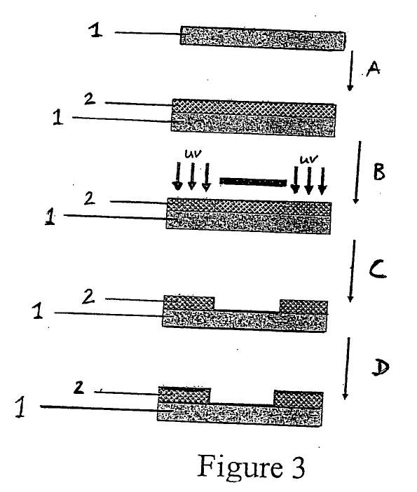

FIG. 3. schematically depicts a third method of realising the method of the present invention;

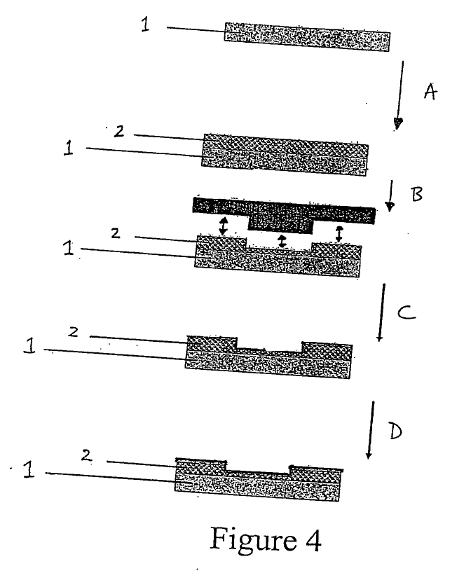

FIG. 4. schematically depicts a fourth method of realising the method of the present invention;

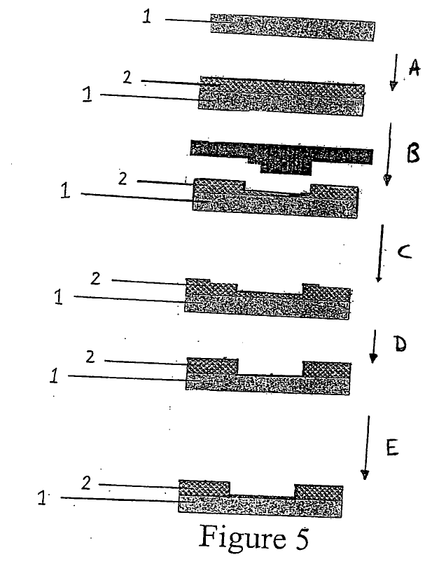

FIG. 5. schematically depicts a fifth method of realising the method of the present invention; and

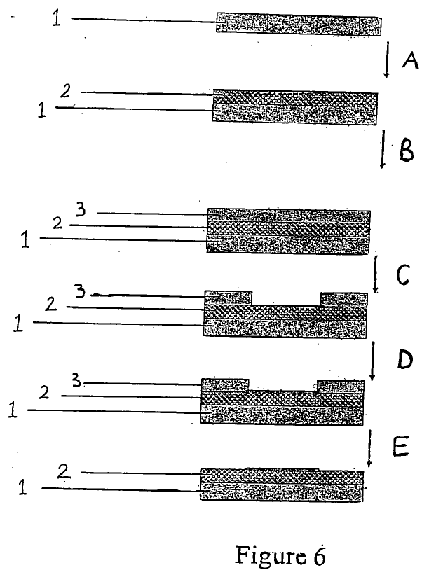

FIG. 6. schematically depicts a sixth method of realising the method of the present invention.

### THE SUBSTRATE

In the context of the present invention, the term “substrate” is not limited to the actual substrate used for instance in the production of a semiconductor element. Rather, “substrate” in this context is intended to encompass any material on which a further element, an electronically functional element, is formed which includes surfaces already coated and/or patterned with e.g. conductors, semiconductors or insulators as intermediate products in the fabrication of e.g. electronic devices such as transistors.

Substrate Precursor and Base

The substrate precursor is the material from which the substrate is produced by etching the precursor. The only necessary requirement for the substrate precursor is that it has on at least part of its surface a surface layer comprising inorganic particles which are embedded in a polymer matrix. Preferably, the inorganic particles are not present at the surface of the surface layer when the substrate precursor is in its unetched form. The substrate precursor may be obtained by coating a substrate base with a mixture of a polymer matrix and inorganic particles in a suitable solvent.

In view of the desirability of using the substrate obtainable by the methods of the present invention in the production of microelectronic components, in particular using reel-to-reel processing, it is preferable if the substrate itself, the substrate precursor and the substrate base (where one is used) are flexible. Preferably, the substrate, the substrate precursor and the substrate base (where one is used) are flexible to the extent that they are rollable so that a roll having a diameter of 10 metres or less can be formed. More preferably, it is possible to roll the substrate, the substrate precursor and the substrate base (where one is used) to form a roll having a diameter of 5 metres or less, even more preferably 2 metres or less and most preferably 1 metre of less.

As mentioned, the substrate precursor may be produced by a preliminary step which comprises coating a substrate base with a mixture of the polymer forming the polymer matrix of the surface layer and inorganic particles in a suitable solvent (e.g. butylacetate), thereby forming the surface layer on the substrate base to yield the substrate precursor. There is no particular limitation on the amount of inorganic particles used relative to the amount of polymer matrix to produce the mixture. Preferably, the inorganic particles constitute 10-70 vol. % of the mixture, more preferably 20-60, most preferably 30-40 vol. % relative to the total amount of polymer and inorganic particles.

Depending on the details of the method of production of the substrate, it may in some cases be preferable to use a precursor obtainable by coating a substrate base with a mixture comprising only a relatively small amount of inorganic particles, for example 10-30, more preferably 15-25 vol. % relative to the total amount of polymer and inorganic particles. In other applications it may be more preferable to use a precursor obtainable by coating a substrate base with a mixture having a relatively high content of the inorganic particles, e.g. 40-60 vol. %, more preferably 45-55 vol. % relative to the total amount of polymer and inorganic particles. As mentioned above, depending on the concentration of the inorganic particles in the polymer and the extent to which the uppermost polymer material is removed from the surface layer, it is possible to produce regions which are essentially glass-like, essentially polymer-like or anywhere in between.

In producing the substrate precursor in this way, either the entire substrate base or only selected areas of the substrate base may be coated with the mixture of the polymer matrix and the inorganic particles. Where the entire surface is to be coated, this can be achieved e.g. by spin-coating or doctor blading.

Where the precursor is a coated substrate base, the thickness of the coating which forms the surface layer is not critical. Preferably, the coating is 0.5-20 μm thick, more preferably 1-10 μm, most preferably 1-5 μm and e.g. 2 μm.

Where a substrate base is used, its identity is not particularly limited, although, for the reasons explained above, it is preferable to use a flexible substrate base. The thickness of the base is also not important, although if the substrate is to be used in reel-to-reel processing, it may be preferable to use a relatively thin substrate base (e.g. 20-1000 μm, preferably 50-500 μm, most preferably 100-150 μm) in view of obtaining a flexible substrate. Specific examples of substrate bases include metal foils (e.g. aluminium or steel) and polymer foils produced from polyimide (PI), polyethylene terephthalate (PET), polyethylene naphthalate (PEN), polycarbonate (PC), polynorbornene (PNB) and polyethersulfone (PES).

Where it is desired to use a hydrophilic substrate base, foils made from or coated with e.g. a thin metal layer (e.g. aluminium or steel), regenerated celluloses, polyvinyl alcohol, polyvinylphenol (PVP) or polyvinylpyrrolidone can be used.

Where it is desired to use a hydrophobic substrate base, polymers such as polyimide (PI), polyethylene terephthalate (PET), polyethylene naphthalate (PEN), polycarbonate (PC), polynorbornene (PNB) and polyethersulfone (PES) can be used.

Polymer Matrix Materials

The polymer matrix material which forms part of the surface layer of the substrate precursor is preferably chosen from materials already used in the field of preparing substrates for use in the preparation of microelectronic components in view of the fact that skilled workers are already familiar with such materials. Currently used materials are, for example, polyimides (PI), benzocyclobutene (BCB), epoxy-based negative resists (e.g. SU-8), photo-initiated curing acrylates (e.g. Delo-photobond), polyacrylates (e.g. polymethylmethacrylate, (PMMA)), polymethylglutarimide (PMGI) and polyvinylphenol. Preferably, the polymer matrix material is PMMA. The mixture of polymer matrix, inorganic oxide particles and solvent may for example be prepared by mechanical mixing or using ultrasonic mixing.

Inorganic Particles

In the present invention, it is in principle possible to use any inorganic material provided that it has the appropriate properties for producing the desired wetting contrast. The inorganic material used is preferably an inorganic oxide. For the purposes of the present invention, the term “inorganic oxide” is taken to encompass non-organic materials which are solid at room temperature and at ambient pressure and which have an oxygen atom. Thus minerals containing oxygen atoms are for the purposes of the present invention classed as inorganic oxides, as are the solid oxides of metals (e.g. aluminium and titanium) and the solid oxides of semi-metals (e.g. silicon). Inorganic oxides which can be used include binary oxides (such as silicon dioxide (SiO₂), aluminium oxide (Al₂O₃), titanium dioxide (TiO₂), tin oxide (SnO₂) and tantalum pentoxide (Ta₂O₅)), ternary oxides (such as indium tin oxide (ITO) and perovskites (e.g. CaTiO₃ or BaTiO₃)) and quaternary oxides such as zeolites (Mⁿ⁺_{x/n}[(AlO₂)ₓ(SiO₂)_{y}].mH₂O).

Furthermore, in addition to the above-mentioned oxides, any material or material combination that turns hydrophilic upon exposure to O₂ plasma and/or CF₄ plasma (by initial formation of a fluorine terminated surface that reacts with water to form a hydroxy-terminated surface) may be used. Specific examples include elemental metals or semiconductors such as aluminium, tin, titanium, aluminium-copper alloys, silicon and germanium; metal chalcogenides such as tin sulphide and tungsten selenide; metal nitrides such as boron nitride, aluminium nitride, silicon nitride and titanium nitride; metal phosphides such as indium phosphide; carbides such as tungsten carbide and silicon carbide; and metal silicides such as copper silicide.

The inorganic particles preferably have an average particle size as measured by Transmission Electron Microscopy (TEM) of less than 5 μm, more preferably less than 0.5 μm, most preferably less than 0.05 μm. The particles are preferably nanoparticles having an average size in the range 5-1000 nm, more preferably 5-100 nm, most preferably 10-20 mm. Such small particles are preferable for a number of reasons.

Firstly, small particles result in better optical quality of the resulting substrates. For particle sizes smaller than the wavelength of the visible light, light scattering is avoided and a clear particle-polymer composite film can be obtained. This is important where the substrate is used in display applications.

Secondly, small particles result in an appropriate roughness of the surface layer. Nanoparticles are preferable to micron-sized particles, as the latter result in a surface roughness of the composite film on a scale corresponding to the particle sizes. Although it is generally preferable for a substrate to have a rough surface, there is a limit to how rough a surface can be and still allow appropriate end products (e.g. microelectronic components) to be produced. Substrates for microelectronic applications should have a surface roughness below the required pattern sizes. Therefore, the use of nanoparticles allows the surface area of the substrate surface to be increased without roughening the surface to the extent that further processing becomes difficult.

Thirdly, small particles are preferably used in view of the chemical homogeneity of the substrate. In order to achieve high-resolution patterning by inkjet printing, the lateral variations in the surface composition, which result in a corresponding variation of the surface energy, should preferably be on a scale smaller than the required pattern sizes.

Etching Treatments

According to the method of the present invention, polymer is etched away from an area of the surface layer of a substrate precursor, the surface layer comprising inorganic particles which are embedded in a polymer matrix. The etching step serves to expose underlying inorganic particles at the surface of the substrate precursor, the exposed area corresponding to one of two adjacent areas of the substrate differing in hydrophilicity and/or oleophilicity. In terms of carrying out the etching step, this is preferably achieved by treating the surface layer with a plasma. In terms of types of plasma which can be used, O₂ plasma, CF₄ plasma and mixtures thereof are mentioned. Suitable plasma treatment could for example be carried out by contacting the surface with plasma of one of the above types for a period of 5-60 seconds, more preferably 10-30 seconds, more preferably 20 seconds at a flow rate of 200 ml/min and at a power of 200 W using a Branson/IPC Series S2100 plasma stripper system equipment. Where other equipment is used, other durations, flow rates and power may be appropriate. Those skilled in the art can readily select appropriate settings on such apparatuses to achieve the desired etching. Where it is desired to carry out the plasma etching treatment only on one part of the surface layer of the substrate precursor, it is possible to create a photoresist pattern on the surface layer prior to etching, the photoresist ensuring that the areas of the surface layer which are covered are not etched. The photoresist would then be removed after the etching step has been carried out by exposure of the entire surface of the precursor to the plasma to reveal unetched areas underlyng the patterned photoresist. A photoresist pattern can for example be produced by coating the substrate precursor with a UV crosslinkable photoresist material, and irradiating the coating with UV light through a photomask to crosslink the irradiated areas. The non-crosslinked photoresist material is then dissolved to create the photoresist pattern.

Whilst it is preferable that the etching step of the method of the present invention is carried out by plasma, it is not excluded that other etching techniques could be used such as for example etching by exposure to an etching solution or to an organic solvent that specifically dissolves the matrix polymer, thus leaving the inorganic particles exposed on the surface. Where an etching solution is used, this is preferably oxidative, meaning that the organic matrix polymer is removed by oxidation in order to expose the inorganic particles. Wet-chemical treatment with strongly oxidising substances such as a concentrated ammonium hydroxide-hydrogen peroxide solution or a potassium permanganate solution could for example be used. Use of etching solutions is less preferable than using plasma due to inevitable contamination of the substrate with residual ions from the etching solution.

Chemical Treatments

According to the present invention, substrates may be subjected to various chemical treatments in order to increase the difference in hydrophilicity and/or oleophilicity between the adjacent areas which make up the wetting contrast relative to the substrate prior to chemical treatment. Furthermore, chemical treatment may allow a substrate to be modified so that an appropriate wetting contrast is available for the intended use; this is important because sometimes not only the physical surface properties of the areas which make up the wetting contrast but also the chemical properties are important. Whilst many types of chemical treatment could in principle be used to modify the substrates or to increase the difference in hydrophilicity and/or oleophilicity, only the following three types of treatment are discussed in detail herein; other chemical treatment methods which can be used in the present invention will be apparent to those skilled in the art. The three types of treatment discussed herein are: (i) fluorination treatment, (ii) oxidation treatment and (iii) fluoroalkylsilane treatment.

(i) Fluorination Treatment

Fluorination of a surface is achieved by chemical treatment, for example with SF₆ or CF₄ plasma.

Treatment by exposure of a surface to CF₄ plasma fluorinates even relatively unreactive moieties on that surface. Thus, for example, where an alkyl moiety is present on the surface, it will become fluorinated. As fluorocarbon moieties are hydrophobic and oleophobic, fluorination of common polymer materials such as polymethylmethacrylate (PMMA), polyimide (PI) and polyethylene terephthalate (PET) will render them hydrophobic and oleophobic.

In contrast, fluorination of the surface of an inorganic material will result in the formation of the corresponding inorganic fluorides, which are most often reactive towards nucleophiles such as water molecules and form a hydrophilic hydroxyl-terminated surface upon exposure to water. For example, fluorination of SiO₂ results in the formation of Si—F bonds. Si—F bonds are relatively unstable, and are converted to Si—OH groups when exposed to moist air or water.

Where a polymer matrix comprising inorganic particles is exposed to CF₄ plasma, the concentration of inorganic particles at the surface is important in determining whether the surface is rendered hydrophilic or hydrophobic and oleophobic. A large concentration of inorganic particles at the surface will make the material behave more like the inorganic material and less like the matrix material, yielding a hydrophilic surface on fluorination. In contrast, where only a low surface concentration of the inorganic particles is present, the material will act more like the matrix polymer and will yield a hydrophobic and oleophobic surface upon fluorination. Prolonged exposure of a low concentration matrix of inorganic particles to CF₄ plasma will tend to make the surface more hydrophilic, as the matrix material becomes etched away by the plasma revealing a greater surface area of the inorganic particles. Treatment of hydroxylated groups with CF₄ plasma effectively replaces the —OH moieties with —F moieties, probably by etching away the surface layer containing the OH-bonds and providing a newly formed surface which is F-terminated. Whilst CF₄ plasma treatment is often used in laboratory scale production of wetting contrasts on inorganic substrates, it is preferable not to use such steps in commercial manufacture of these as a vacuum chamber is required to carry out plasma treatment. This is generally not practical in a factory setting, and adds expenditure.

(ii) Oxidation Treatment

Oxidation of a surface is achieved by chemical treatment, for example with O₂ plasma, ozone/UV or by corona discharge treatment in air.

Treatment by exposure of a surface to O₂ plasma oxidises even relatively unreactive moieties on that surface. Thus, for example, where an alkyl moiety is present on the surface, it will become oxidised, forming hydroxyl, carbonyl, and carboxylic acid groups. As hydroxyl and carboxylic acid moieties are hydrophilic, oxidation of common polymer materials such as polymethylmethacrylate (PMMA), polyimide (PI), and polyethylene terephthalate (PET), will render them hydrophilic.

Exposure of an inorganic material to O₂ plasma similarly introduces hydrophilic hydroxyl groups after exposure to atmospheric moisture or water.

Thus, oxidation treatment, e.g. by exposure to O₂ plasma, renders both inorganic materials and polymers hydrophilic. It follows that also exposure to a surface comprising an inorganic material and a matrix polymer results in a hydrophilic surface, regardless of the surface concentration of the inorganic material. Whilst O₂ plasma treatment is often used in laboratory scale production of wetting contrasts, it is preferable not to use such steps in commercial manufacture of these as a vacuum chamber is required to carry out plasma treatment. This is generally not practical in a factory setting, and adds expenditure. Alternatives include UV-ozone or corona (electrical discharge) treatments.

(iii) Fluoroalkylsilane Treatment

Treatment of a surface, for example by exposure to a material such as (heptadecafluorodecyl)-trichlorosilane (CF₃(CF₂)₇CH₂CH₂SiCl₃) in hexane results in the grafting of fluoroalkylsilane molecules onto reactive moieties on the surface such as hydroxyl groups. Thus fluoroalkylsilane molecules become grafted to the surface oxygen atoms of an inorganic material surface treated with e.g. (heptadecafluorodecyl)-trichlorosilane (CF₃(CF₂)₇CH₂CH₂SiCl₃) in hexane. This renders the surface super-hydrophobic and oleophobic. Where an inorganic material has no moieties which are reactive towards fluoroalkyl silanes, an oxidation treatment may be required before exposure to the fluoroalkylsilane.

Exposure of a pristine polymer to a fluoroalkylsilane treatment has no effect, as C—H bonds are not reactive towards trichlorosilanes under the reaction conditions usually applied for silanisations. It is possible to graft fluoroalkylsilanes to an oxidised polymer that contains hydroxyl moieties, for example a polymer oxidised by exposure to O₂ plasma. However, the C—O—Si bonds which are formed are easily cleaved by hydrolysis or reaction with other nucleophiles. For this reason, a fluoroalkylsilane treatment is generally not used to render polymer surfaces hydrophobic and oleophobic and their use is in practice restricted to the modification of inorganic substrates.

The effect of silanisation with a fluoroalkylsilane of a polymer matrix comprising inorganic particles depends on the concentration of inorganic hydroxyl groups at the surface. Where the concentration is high, the surface is rendered super-hydrophobic and oleophobic. The less inorganic hydroxyl groups there are present at the surface, the less this is observed.

Producing Substrates Having Hydrophilic vs. Hydrophobic and Oleophobic Wetting Contrasts

The present invention provides several specific ways in which substrates having hydrophilic vs. hydrophobic/oleophobic wetting contrasts can be produced.

According to a first method depicted schematically in FIG. 1, a substrate having a hydrophilic vs. hydrophobic and oleophobic wetting contrast is prepared by coating a substrate base (1) (e.g. a polyimide (PI), polyethylene terephthalate (PET), polyethylene naphthalate (PEN), polycarbonate (PC), polynorbornene (PNB) or polyethersulfone (PES) sheet with e.g. a thickness of 100-150 μm and A4 (210×297 mm) dimensions) with a polymer (2) (e.g. polymethylmethacrylate (PMMA)) comprising particles (e.g. nanoparticles of average particle size 10-20 nm) of an inorganic material (e.g. SiO₂) (Step A). The inorganic material may for example be present in the polymer in an amount of 20 vol. %. For example, a 1 μm thick layer of polymer matrix and inorganic particles could be applied to the substrate base by spin-coating or doctor-blading. The coated substrate base is then left to dry, to form a substrate precursor.

Subsequently, the substrate precursor is coated with a photoresist material (3) (e.g. by spin-coating a Shipley photoresist S1800 series) (Step B) which is then removed in a pattern as desired (e.g. using UV exposure through a photomask, followed by a photoresist development with MF 319 developer) to reveal a pattern of the underlying polymer and inorganic particle layer (Step C). Then, the surface is exposed to a prolonged surface oxidation treatment (e.g. by O₂ plasma for 20 seconds at a flow-rate of 200 ml/min and at a power of 200 W) which etches away a portion of the polymer matrix surrounding the inorganic particles, thus revealing the inorganic particles at the surface and rendering the treated part of the surface hydrophilic (Step D). Next, the photoresist (3) is removed (e.g. by Microposit remover 1165) (Step E) to form the substrate. In a final step (Step F), the entire surface of the substrate is exposed to a short CF₄ plasma treatment (e.g. 7 seconds at a flow-rate of 200 ml/min and at a power of 200 W), which retains the hydrophilicity of the previously oxygen plasma-etched areas which are high in surface inorganic material concentration but renders the previously photoresist-covered, non-oxygen plasma-etched areas which are low in surface inorganic material concentration hydrophobic and oleophobic.

According to a second method, depicted schematically in FIG. 2, a substrate having a hydrophilic vs. hydrophobic and oleophobic wetting contrast is prepared by coating a substrate base (1) (e.g. polyimide (PI), polyethylene terephthalate (PET), polyethylene naphthalate (PEN), polycarbonate (PC), polynorbornene (PNB) or polyethersulfone (PES) sheet with e.g. a thickness of 100-150 μm and A4 (210×297 mm) dimensions) with a composition comprising a polymer (2) (e.g. PMMA), particles (e.g. nanoparticles of average particle size 10-20 nm) of an inorganic material (e.g. SiO₂) and a solvent (e.g. butylacetate) (Step A). The inorganic material may for example be present in the polymer (2) in an amount of 50 vol. % relative to the total amount of polymer and inorganic particles. For example, a 1 μm thick layer of polymer matrix and inorganic particles could be applied to the substrate base by spin-coating or doctor-blading. The coated substrate base is then left to dry, to form a substrate precursor.

The substrate precursor is coated with a polymer (4) (e.g. polyvinylpyrrolidone) comprising a crosslinker (e.g. a UV crosslinker such as divinylbenzene) (Step B). The polymer coating (4) may be applied in a thickness of e.g. 2 μm, and the crosslinker may be comprised in an amount of e.g. 2-5 wt. %. The polymer coating is then selectively exposed to crosslinking conditions (e.g. UV light where a UV crosslinker is used) in a patterned area (Step C). The surface is then washed with an appropriate solvent (e.g. water where a polyvinylpyrrolidone polymer is used) to remove to the polymer (4) from areas which were not crosslinked (Step D). The underlying polymer (2) and inorganic particle layer will thus be exposed in these areas. Subsequently, the surface is etched and exposed to a fluorinating agent (e.g. performing both of these by exposure to CF₄ plasma for 7 seconds at a flow-rate of 200 ml/min and at a power of 200 W), which renders the crosslinked polymer areas (4) hydrophobic/oleophobic and renders the polymer (2) and inorganic material layer hydrophilic by etching away the uppermost polymer layer from the surface and exposing the inorganic particles (Step E).

According to a third method, depicted schematically in FIG. 3, a substrate having a hydrophilic vs. hydrophobic and oleophobic wetting contrast is prepared by coating a substrate base (1) (e.g. a polyimide (PI), polyethylene terephthalate (PET), polyethylene naphthalate (PEN), polycarbonate (PC), polynorbornene (PNB) or polyethersulfone (PES) sheet with e.g. a thickness of 100-150 μm and A4 (210×297 mm) dimensions) with a composition comprising a photocrosslinkable polymer (2) (e.g. polystyrene), particles (e.g. nanoparticles of average particle size 10-20 nm) of an inorganic material (e.g. SiO₂), a crosslinker (e.g. a UV crosslinker such as divinylbenzene) and a solvent (e.g. butylacetate) (Step A). The inorganic material may for example be present in the polymer (2) in an amount of e.g. 50 vol. % relative to the total amount of polymer and inorganic particles. The crosslinker may for example be present in an amount of e.g. 5 wt. % of the composition. For example, a 2 μm thick layer of polymer matrix and inorganic particles could be applied to the substrate base by spin-coating or doctor-blading. The coated substrate base is then left to dry, to form a substrate precursor.

The substrate precursor is then selectively exposed to crosslinking conditions (e.g. UV light where a UV crosslinker is used) in a patterned area (Step B). The surface is then washed with an appropriate solvent (e.g. mesitylene where polystyrene is used) to remove to the polymer (2) and inorganic material from areas which were not crosslinked, to reveal the underlying substrate base (1) (Step C). Subsequent treatment of the surface with CF₄ plasma (e.g. by exposure to CF₄ plasma for 7 seconds at a flow-rate of 200 ml/min and at a power of 200 W) renders the polymer precursor areas (1) hydrophobic and oleophobic, but removes the top layer of polymer from the inorganic particle-containing polymer (2) layer by etching to reveal the inorganic particles at the surface and render it hydrophilic (Step D).

According to a fourth method, depicted schematically in FIG. 4, a substrate having a hydrophilic vs. hydrophobic and oleophobic wetting contrast is prepared by coating a substrate base (1) (e.g. a polyimide (PI), polyethylene terephthalate (PET), polyethylene naphthalate (PEN), polycarbonate (PC), polynorbornene (PNB) or polyethersulfone (PES) sheet with e.g. a thickness of 100-150 μm and A4 (210×297 mm) dimensions) with a composition comprising a polymer (2) (e.g. PMMA), particles (e.g. nanoparticles of average particle size 10-20 nm) of an inorganic material (e.g. SiO₂) and a solvent (e.g. butylacetate) (Step A). The inorganic material may for example be present in the polymer (2) in an amount of 50 vol. % relative to the total amount of polymer and inorganic particles. For example, a 2 μm thick layer of a mixture of polymer matrix and inorganic particle could be applied to the substrate base by spin-coating or doctor-blading. The coated substrate base is then left to dry, to form the substrate precursor.

The substrate precursor is then micro-embossed to form a patterned area where the polymer layer (2) is compressed (Step B). This can for example be achieved using a hard stamp at a temperature above the glass transition temperature of the matrix polymer. The surface is then oxidised (e.g. by exposure to O₂ plasma for 7 seconds at a flow-rate of 200 ml/min and at a power of 200 W) to render the entire surface hydrophilic (Step C). A fluoroalkylsilane (e.g. heptadecafluorodecyl)-trichlorosilane) is then applied to the surface areas which were not embossed, by application e.g. via a non-patterned (flat) polydimethylsiloxane (PDMS) stamp (Step D). This renders the unembossed (surface) areas hydrophobic and oleophobic.

According to a fifth method, depicted schematically in FIG. 5, a substrate having a hydrophilic vs. hydrophobic and oleophobic wetting contrast is prepared by coating a substrate base (1) (e.g. a polyimide (PI), polyethylene terephthalate (PET), polyethylene naphthalate (PEN), polycarbonate (PC), polynorbornene (PNB) or polyethersulfone (PES) sheet within e.g. 100-150 μm thickness, A4 (210×297 mm) dimensions) with a composition comprising a polymer (2) (e.g. PMMA), particles (e.g. nanoparticles of average particle size 10-20 nm) of an inorganic material (e.g. SiO₂) and a solvent (e.g. butylacetate) (Step A). The inorganic material may for example be present in the polymer (2) in an amount of 50 vol. % relative to the total amount of polymer and inorganic particles. For example, a 2 μm thick layer of polymer matrix and inorganic particles could be applied to the substrate base by spin-coating or doctor-blading. The coated substrate base is then left to dry, to form the substrate precursor.

The substrate precursor is then micro-embossed (e.g. using a hard stamp at a temperature above the glass transition temperature of the matrix polymer) to form a patterned area where the polymer layer (2) is compressed (Step B). The surface is then oxidised (e.g. by exposure to O₂ plasma for 7 seconds at a flow-rate of 200 ml/min and at a power of 200 W) to render the entire surface hydrophilic (Step C). Then, the polymer (2) and inorganic particle layer is removed from the embossed areas (e.g. by de-scumming treatment with a mixed O₂/CF₄ plasma for 1 minute at a flow-rate of 200 ml/min and at a power of 200 W) to expose the base (1) in the embossed areas (Step D). Subsequent exposure of the surface to CF₄ plasma renders the exposed precursor hydrophobic and oleophobic, while the non-embossed areas are etched and rendered hydrophilic (Step E).

The five methods described above all result in substrates having wetting contrasts wherein the two areas making up the wetting contrast have a large difference in hydrophilicity and or oleophilicity but where one of the surfaces in question is fluorinated. The substrate obtainable by these methods are superior to those known from the prior art mainly because the difference in hydrophilicity and/or oleophilicity achievable is significantly higher than that obtainable using conventional techniques. This is because one of the effects of the inclusion of inorganic oxide particles at or near the surface of the precursor is to increase the surface area, thus rendering hydrophilic areas more hydrophilic, hydrophobic areas more hydrophobic, oleophilic areas more oleophilic and oleophobic areas more oleophobic. Furthermore, the methods of the present invention as exemplified by the five methods described above have the advantage that it is not necessary to carry out these methods on a rigid substrate such as a plate of glass or indium tin oxide. Instead, because one of the surface layers can be glass-like in behaviour, it is possible to use any substrate base so that it possible to produce a flexible substrate which can be used in reel-to-reel processing.

Producing Substrates Having Hydrophilic vs. Hydrophobic and Oleophilic Wetting Contrasts

According to a sixth method depicted schematically in FIG. 6, a substrate having hydrophilic vs. hydrophobic and oleophilic wetting contrasts is prepared by coating a substrate base (1) (e.g. a polyimide (PI), polyethylene terephthalate (PET), polyethylene naphthalate (PEN), polycarbonate (PC), polynorbornene (PNB) or polyethersulfone (PES) sheet with e.g. a thickness of 100-150 μm and A4 (210×297 mm) dimensions) with a composition comprising a polymer (2) (e.g. polymethylmethacrylate (PMMA)), particles (e.g. nanoparticles of average particle size 10-20 nm) of an inorganic material (e.g. SiO₂) and a solvent (e.g. butylacetate) (Step A). The inorganic material may for example be present in the polymer in an amount of 50 vol. % relative to the total amount of polymer and inorganic particles. For example, a 1 μm thick layer of polymer matrix and inorganic particles could be applied to the substrate base by spin-coating or doctor-blading. The coated substrate base is then left to dry, to form a substrate precursor.

Subsequently, the substrate precursor is coated with a photoresist material (3) (e.g. Shipley photoresist S1800 series) (Step B) which is then removed in a pattern as desired using e.g. UV exposure through a photomask, followed by a photoresist development with MF 319 developer) to reveal a pattern of the underlying polymer and inorganic material layer (Step C). Then, the surface is exposed to a surface oxidation treatment (e.g. by O₂ plasma for 7 seconds at a flow-rate of 200 ml/min and at a power of 200 W) which etches away a portion of the polymer matrix surrounding the inorganic particles, thus revealing the inorganic particles at the surface and rendering the treated part of the surface hydrophilic (Step D). Next, the photoresist (3) is removed (e.g. by Microposit remover 1165) (Step E) to form the substrate.

The resulting substrate has a good wetting contrast formed between the etched and unetched areas of the surface layer of the substrate wherein the difference in hydrophilicity and/or oleophilicity between these areas is greater than that which is achievable in the prior art (when avoiding fluorinated surfaces) because of the surface roughening caused both in the etched and unetched areas as a result of the presence of the inorganic particles both on and immediately under the surface of the substrate.

Furthermore, unlike in the prior art, it is possible to use a flexible substrate base which allows the production of a flexible substrate which can be used in reel-to-reel processing; such processing is not possible with the present substrates made of rigid materials such as glass or indium tin oxide.

Methods of Producing Microelectronic Components

The most important use of the substrates obtainable by the methods of the present invention and the substrates of the present invention is in the production of microelectronic components by ink-jet printing or otherwise depositing electronically functional inks onto the substrates. In particular, microelectronic components such as thin-film transistors and light-emitting diodes can be produced by appropriate sequential deposition of electronically functional ink onto the substrates, the wetting contrasts helping to direct the electronically functional inks onto appropriate areas of the substrate. In these processes, it is not necessarily the case that all of the elements which make up the microelectronic component are ink-jet printed. Thus, it may be the case that some or all of the elements are deposited by other means. However, it is most preferable to use ink-jet printing to deposit all of the elements making up the microelectronic component on the substrate. It is particularly preferable to deposit any semiconductor layers using ink-jet printing.

For example, the substrates of the present invention could be used to produce a thin-film transistor by ink-jet printing (or otherwise depositing) a conductor solution onto the substrate to form source and drain electrodes, making use of the wetting contrasts to deposit the electrodes accurately. After the conductor ink has dried to form the electrodes, a solution comprising a semiconductor is deposited (e.g. by ink-jet printing) onto the substrate with the electrodes and left to dry. An insulator material is then deposited onto the dried semiconductor material (e.g. by ink-jet printing). Once the insulator material is dry, a gate electrode is formed on the insulator material in appropriate alignment with the source and drain electrodes, thus completing the formation of the thin-film transistor.

The substrates of the present invention can also be used to produce for example a light-emitting diode. This is achieved by firstly ink-jet printing or otherwise depositing a semiconductor material onto a substrate on which an electrode has already been formed (e.g. by ink-jet printing a conductor solution onto the substrate), again making use of the wetting contrast, and leaving the deposited ink to dry to form a charge injection layer. Once the charge injection layer is dry, an emissive semiconductor material is deposited onto the charge injection layer (e.g. by ink-jet printing). Once this is dry, a cathode is formed on the emissive semiconductor material.

### EXAMPLES

The following experimental work was carried out by the present inventors, and supports their findings that substrates comprising wetting contrasts associated with inorganic materials at their surfaces are advantageous in that adjacent surface areas differing greatly in hydrophilicity and/or oleophilicity can be achieved.

### Example 1

### Modification of Surface Properties by Plasma Treatment

Preparation of Substrates

Reference Substrate

A 3% polymethylmethacrylate (PMMA) solution in butylacetate was prepared by dissolving 0.93 g of PMMA (from Sigma Aldrich) in 30 ml butylacetate. 0.5 ml of the solution was spin coated onto a glass substrate (12×12 mm) precursor (7059 from Corning) for 30 seconds at 1500 rpm in air. The coated precursor was then annealed for 10 minutes at 100° C. in air to form a Reference Substrate.

Substrate 1 (B1)

0.028 g of nanoparticulate SiO₂ (hexamethyldisilazane treated silica particles, 10-20 nm, from ABCR) was dispersed in 1 ml 6% PMMA in butylacetate (Aldrich) and 1 ml butylacetate (Aldrich). The mixture was mixed thoroughly by stirring on a magnetic stirrer and by a final ultrasonic mixing step in an ultrasonic bath for 5 minutes to yield a solution comprising 17.3 vol. % SiO₂. 0.5 ml of the solution was spin coated onto a glass substrate precursor (12×12 mm plate, 7059 from Corning) for 30 seconds at 1600 rpm in air. The coated precursor was then annealed for 12 minutes at 100° C. in air to form Substrate 1.

Substrate 2 (B2)

The procedure outlined above for substrate 1 was repeated, except that 0.056 g of SiO₂ was used. The solution thus obtained comprised 29.5 vol. % SiO₂. The solution was spin-coated onto a precursor as in Example 1, except that it was carried out at 2000 rpm.

Substrate 3 (B3)

The procedure outlined above for substrate 1 was repeated, except that 0.085 g of SiO₂ was used and that 1.5 ml of butylacetate was used rather than 1 ml. The solution thus obtained comprised 38.6 vol. % SiO₂. The solution was spin-coated onto a precursor as in Example 1, except that it was carried out at 2000 rpm.

Substrate 4 (B4)

The procedure outlined above for substrate 1 was repeated, except that 0.110 g of SiO₂ was used and that 2 ml of butylacetate was used rather than 1 ml. The solution thus obtained comprised 44.9 vol. % SiO_{2.} The solution was spin-coated onto a precursor as in Example 1, except that it was carried out at 2000 rpm.

Substrate 5 (B5)

The procedure outlined above for substrate 1 was repeated, except that 0.136 g of SiO₂ was used and that 2 ml of butylacetate was used rather than 1 ml. The solution thus obtained comprised 50.4 vol. % SiO₂. The solution was spin-coated onto a precursor as in Example 1, except that it was carried out at 2000 rpm.

Plasma Treatment and Measurements

Substrates 1-5 and the Reference Substrate were rinsed with water. Then the contact angles with water droplets of size 1-5 μl were measured for each of these six substrates using a goniometer (contact angle measuring device).

Subsequently, each of the six substrates was exposed to an O₂ plasma treatment (in a Branson/IPC Series S2100 Plasma Stripper system equipment) for 7 seconds at a flow rate of 200 ml/min and at a power of 200 W. Contact angles of the treated substrates were measured using the same apparatus and methods as above.

Subsequently, each of the six oxidised substrates was exposed to CF₄ plasma in a Branson/IPC Series S2100 Plasma Stripper system for 7 seconds at a flow rate of 200 ml/min and at a power of 200 W. Then the substrates were rinsed with de-ionised water (Elix 10 DI water plant). Contact angles of the treated substrates were measured using the same apparatus and methods as above.

Finally, the film thickness of each of the six substrates was measured using a Dektak 8 stylus profiler technique.

The resulting data is set out in table 2 below:

TABLE 2

| | Ref. | B1 | B2 | B3 | B4 | B5 |
|---|---|---|---|---|---|---|
| Vol. % (SiO₂) in solid film | 0 | 17.3 | 29.5 | 38.6 | 44.9 | 50.4 |
| Spin-coating speed (rpm) | 1500 | 1600 | 2000 | 2000 | 2000 | 2000 |
| I. Initial contact angle after | 74° | 82 | 92° | 100° | 117° | 125° |
| water-rinse | | | | | | |
| II. Contact angle after (5 + 2)s | 7° | 15° | 5° | 5° | 5° | 5° |
| O₂-plasma; flow-rate O₂ 200 ml/min, | | | | | | |
| power 200 W | | | | | | |
| III. Contact angle after (5 + 2)s | 76° | 90° | 53° | 10° | 5° | 5° |
| CF₄-plasma; flow-rate CF₄ 200 ml/ | | | | | | |
| min, power 200 W; measured after | | | | | | |
| water-rinse | | | | | | |
| Final film thickness (nm) | 436 | 530 | 150 | 500 | 350 | 680 |

### Example 2

### Modification of Surface Properties by Silanisation with a Fluoroalkylsilane

Preparation of Substrates

A Reference Substrate and Substrates 1-5 were prepared as in Example 1 above.

Plasma Treatment and Measurements

Substrates 1-5 and the Reference Substrate were rinsed with water. Then the contact angles with water droplets of size 1-5 μl were measured for each of these six substrates using a goniometer (contact angle measuring device).

Subsequently, each of the six substrates was exposed to a CF₄ plasma treatment in a Branson/IPC Series S2100 Plasma Stripper system for 7 seconds at a flow rate of 200 ml/min and at a power of 200 W. Contact angles of the treated substrates were measured using the same apparatus and methods as above. In the substrates with high oxide content (B4 and B5), the inventors observed a fast initial decrease of the contact angles, with the values slowly stabilising after prolonged measurement times. Thus, the contact angle ranges reported in table 3 below for the high oxide content samples correspond to the initial values and the values obtained after 5 minutes measuring time.

Subsequently, each of the six fluorinated substrates were exposed to another CF₄ plasma treatment in a Branson/IPC Series S2100 Plasma Stripper system for 7 seconds at a flow rate of 200 ml/min and at a power of 200 W. Contact angles of the treated substrates were measure using the same apparatus and methods as above. Again, an initial decrease of the contact angles was observed for the samples B4 and B5, with the values slowly stabilising after prolonged measurement times. However, due to the higher initial reaction rate after the second CF₄ plasma treatment, the initial contact angle values could not be determined accurately. Therefore, only the contact angles determined after 5 minutes measuring time are reported in table 3 below.

Subsequently, each of the six substrates was rinsed with de-ionised water (Elix 10 DI water plant) and the contact angles with water were measured again.

Finally, the rinsed substrates were treated with (heptadecafluorodecyl)-trichlorosilane (CF₃(CF₂)₇CH₂CH₂SiCl₃) in an octane solvent. The substrates were blown dry with nitrogen gas and then their contact angles with water were measured again.

The resulting data is set out in table 3 below:

TABLE 3

| | Ref. | B1 | B2 | B3 | B4 | B5 |
|---|---|---|---|---|---|---|
| Vol. % (SiO₂) in | 0 | 17.3 | 29.5 | 38.6 | 44.9 | 50.4 |
| film | | | | | | |
| Contact angle | 75° | 91° | 93° | 118° | 133° | 133° |
| initial | | | | | | |
| (5 + 2)s 200 | 105° | 110 | 116° | 95° | 85° | 85° |
| ml/min CF₄/200 W | | | | | to | to |
| | | | | | 50° | 55° |
| (5 + 2)s 200 | 101° | 110° | 118° | 89° | 45° | 40° |
| ml/min CF₄/200 W | | | | | | |
| Rinsing with water | 100° | 92° | 90° | 57° | 27° | 30° |
| Fluoro-SAM in | | 110° | 127° | 145° | 140° | 145° |
| octane | | | | | | |

Data Analysis

From the above data, it can be seen that it is possible to create highly hydrophilic and highly hydrophobic surfaces from substrate precursors having a surface layer comprising inorganic oxide particles which are embedded in a polymer matrix. Thus it is possible to manufacture substrates comprising good wetting contrasts by carrying out the methods 1-6 described above, as well as by other methods known to the person skilled in the art, all of which make use of substrate precursors having a surface layer comprising inorganic particles which are embedded in a polymer matrix.

Best Mode

The best mode of the present invention is to prepare the substrate using the sixth method of the present invention as described above. This method allows the production of a flexible substrate without the need for surface fluorination, the substrate having a good wetting contrast between the etched and unetched areas of the surface layer of the substrate wherein the difference in hydrophilicity and/or oleophilicity between these areas is greater than that which is achievable in the prior art (when avoiding fluorinated surfaces) because of the surface roughening caused both in the etched and unetched areas as a result of the presence of the inorganic particles both on and immediately under the surface of the substrate.

Furthermore, the sixth method can be performed using a flexible substrate base, which makes it the end substrates useful in reel-to-reel processing.

Preferably, the sixth method is carried out in the following manner:

A substrate having hydrophilic vs. hydrophobic and oleophilic wetting contrasts is prepared by spin-coating onto a substrate base (1) (a pre-treated clear polyester substrate precursor heat-stabilised, 125 μm thickness, 45×45 mm, from Coveme, Italy) a 1 μm thick layer of a solution of a polymer (2) (polymethylmethacrylate (PMMA)) and SiO₂ nanoparticles of average particle size 10-20 nm in butylacetate, the solution comprising SiO₂ particles in an amount of 50 vol. % relative to the total amount of polymer and inorganic particles, to form a substrate precursor.

Subsequently, the substrate precursor is coated with a Shipley photoresist S1800 series photoresist material which is then removed in a pattern as desired by UV exposure through a photomask followed by photoresist development with MF 319 developer to reveal a pattern of the underlying polymer and oxide layer. Then, the surface is exposed to a surface oxidation treatment by using a Branson/IPC Series S2100 Plasma Stripper System, etching with O₂ plasma for 7 seconds at a flow-rate of 200 ml/min and at a power of 200 W to remove a portion of the polymer matrix surrounding the inorganic oxide particles, thus revealing the inorganic oxide particles at the surface and rendering the treated part of the surface hydrophilic. Finally, the photoresist (3) is removed using Microposit remover 1165 to form the substrate.

1. A method of producing a substrate having a surface comprising adjacent areas which have different hydrophilicities and/or oleophilicities comprising the step of etching away polymer from an area of the surface layer of a substrate precursor, the surface layer comprising inorganic particles which are embedded in a polymer matrix, the etching exposing the inorganic particles at the surface in an area corresponding to one of the adjacent areas.

2. A method according to claim 1, wherein the method further comprises the preliminary step of coating a substrate base with a mixture comprising the polymer forming the polymer matrix and inorganic particles to form the surface layer.

3. A method according to claim 2, further comprising the step of pattemwise removing a part of the surface layer, either before or after etching, to re-expose an area of the underlying substrate base adjacent to the area corresponding to the etched area of the surface layer.

4. A method according to claim 1, wherein the substrate comprises an area corresponding to an unetched area of the surface layer adjacent to the area corresponding to the etched area.

5. A method according to claim 4, wherein the area corresponding to the unetched area of the surface layer comprises substantially no inorganic particles at the surface.

6. A method according to claim 1, comprising the step of depositing on an area of the surface layer a polymer different from the polymer comprised in the surface layer, the deposited area being adjacent to the area corresponding to the etched area of the substrate.

7. A method according to claim 1, wherein the difference in hydrophilicity and/or oleophilicity between the adjacent areas is such that these areas differ in their contact angles with hexane by 60° or more and/or with water by 80° or more.

8. A method according to claim 1, wherein the inorganic particles have an average particle size of less than 0.2 mm.

9. A method according to claim 1, wherein the inorganic particles are inorganic oxide particles.

10. A method according to claim 1, wherein the etching step comprises plasma etching away part of the polymer of the surface layer.

11. A method according to claim 1, further comprising, subsequent to the etching step, chemically treating the surface of the substrate to increase the difference in hydrophilicity and/or oleophilicity between the adjacent areas relative to the substrate prior to chemical treatment.

12. A method according to claim 11, wherein the chemical treatment comprises exposing the surface of the substrate to a fluorinating agent.

13. A method according to claim 11, wherein the chemical treatment comprises exposing the surface of the substrate to a fluouroalkylsilanazing agent.

14. A method according to claim 1, wherein one area of the surface of the substrate is hydrophilic and an adjacent area is hydrophobic and oleophobic.

15. A method according to claim 1, wherein one area of the surface of the substrate is hydrophilic and an adjacent area is hydrophobic and oleophilic.

16. A method of producing a modified substrate having a surface which comprises one area which is hydrophobic and oleophilic and an adjacent area which is hydrophobic and oleophobic, the method comprising the steps of:
(i) producing a substrate by the method of claim 15; and
(ii) exposing the surface of the substrate to a fluoroalkylsilanation agent.

17. A method or producing a microelectronic component, comprising the step of:
(i) producing a substrate or a modified substrate having adjacent areas of different hydrophilicity and/or oleophilicity on the same surface by a method as defined in claim 1; and
(ii) depositing a first solution onto the substrate or the modified substrate to form an area comprising a first electronically finctional material.

18. A method according to claim 17, wherein the microelectronic component is a thin-film transistor and the first electronically finctional material is a semiconductor material; and the method further comprises the step of:
(iii) prior to steps (ii), depositing a second solution onto the substrate or modified substrate to form source and drain electrodes so that these underlie the area formed in step (ii);
(iv) depositing a third solution onto the semiconductor material to form an insulating layer; and
(v) forming a gate electrode on the insulator material in appropriate alignment with the source and drain electrodes.

19. A method according to claim 17, wherein the microelectronic component is a light emitting diode, and the first electronically functional material is a semiconductor material which constitutes a charge injection layer, and the substrate or modified substrate comprises an anode, the method further comprising the steps of:
(iii) depositing a fourth solution onto the first semiconductor material to form an area comprising a second emissive semiconductor material; and
(iv) forming a cathode on the second semiconductor material.

20. A method according to claim 17, wherein the deposition of the solutions is carried out by ink-jet printing.

21. A method according to claim 17, which is carried out using reel-to-reel processing.

22. A substrate precursor comprising a surface layer comprising inorganic particles which are embedded in a polymer matrix.

23. A substrate having a surface layer comprising inorganic particles which are embedded in a polymer matrix, the substrate comprising a first surface area where inorganic particles are exposed at the surface and a second surface area, adjacent to the first surface area, where substantially no inorganic particles are exposed.

24. A substrate produced by the method of claim 1, wherein the substrate is a polymer substrate.

25. (canceled)

26. A method of producing a microelectric component, comprising at least one substrate produced by the method of claim 1.
